(19) United States
(12) Patent Application Publication
(10) Pub. No.: US 2004/0017187 A1
(43) Pub. Date: Jan. 29, 2004

(54) Magnetoresistive linear position sensor

(76) Inventors: Kent E. Van Ostrand, Freeport, IL (US); Edward L. Stern, Lanark, IL (US); Wayne A. Lamb, Freeport, IL (US)

Correspondence Address: Andrew A. Abeyta, Honeywell International Inc., 101 Columbia Road, POB 2245, Morristown, NJ, 07962, US

(21) Appl. No.: 10/205,341

(22) Filed: Jul. 24, 2002

(51) Int. Cl. G01B 7/14; G01R 33/09

(52) U.S. Cl. 324/207.21; 324/207.24

(57) ABSTRACT

A sensor method and system for detecting linear position is disclosed. At least one sensing bridge circuit can be configured from at least two separate sensing bridges that share a common geometrical center and are rotated from one another to provide signal offsets thereof. At least one magnet has a north pole and a south pole thereof, such that the sensing bridge circuit is disposed a particular distance from the magnet to provide sinusoidal shaped signals, which can be utilized to determine travel and, thus, a linear position associated with the magnet.

### TECHNICAL FIELD

The present invention is generally related to sensing methods and systems. The present invention is additionally related to sensors utilized in automotive and mechanical applications. The present invention is also related to magnetoresistors and Wheatstone bridge circuit configurations. The present invention is additionally related to linear position sensing methods and systems thereof.

### BACKGROUND OF THE INVENTION

Various sensors are known in the magnetic-effect sensing arts. Examples of common magnetic-effect sensors include Hall effect and magnetoresistive technologies. Such magnetic sensors will generally respond to a change in the magnetic field as influenced by the presence or absence of a ferromagnetic target object of a designed shape passing by the sensory field of the magnetic-effect sensor. The sensor can then provide an electrical output, which can be further modified as necessary by subsequent electronics to yield sensing and control information. The subsequent electronics may be located either onboard or outboard of the sensor package.

Many automotive electronic systems make use of position sensors. When position sensors for automotive electronic systems were originally conceived and developed, such sensors were primarily utilized for the determination of clutch pedal and shift lever positions in automobile transmission applications. Reasonably accurate linear position sensing was required to identify the positions of the clutch pedal and the shift lever, using electrical signals from a non-contacting sensor approach. For example, in automated manual transmission applications, two sensors may be required to sense the shift lever position as it moves in an H-pattern from Reverse to Low to Second to Third gear. For a standard automatic transmission application, where the shift lever moves along a single axis direction, one position sensor may be required to sense whether the shift lever is in one of the Drive-Mode operating positions (i.e., Park, Reverse, Neutral, Drive, Low) as well as positions between such operating conditions.

To date, most position sensors utilized in automotive applications have attempted to utilize Hall-effect position sensors to detect a varying magnetic field. One of the primary problems with this approach is the inability of such systems to accurately detect position. Such systems are unable to effectively eliminate signal response variations due to changes in permanent magnet strengths and also due to dimensional changes occurring in the gap distance between the Hall sensing element and the permanent magnet. The present inventors have thus concluded based on the foregoing that a need exists for an improved linear position sensor, which avoids the aforementioned problems and is adaptable to varying position sensing systems regardless of magnet strengths and dimensions.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide an improved sensor method and system.

It is another aspect of the present invention to provide for a sensor that can be used in automotive and mechanical applications.

It is an additional aspect of the present invention to provide an improved sensor that includes magnetoresistors and Wheatstone bridge circuit configurations thereof.

It is also an aspect of the present invention to provide linear position sensing methods and systems thereof.

The aforementioned aspects of the invention and other objectives and advantages can now be achieved as described herein. A sensor for detecting linear position, including a method thereof, is disclosed herein. At least one sensing bridge circuit can be configured from at least two separate sensing bridges that share a common geometrical center and are rotated from one another to provide signal offsets thereof. At least one magnet has a north pole and a south pole thereof, such that the sensing bridge circuit is disposed at a particular distance from the magnet to provide sinusoidal shaped signals, which can be utilized to determine travel and, thus, a linear position associated with the magnet.

The sensing bridges that form the sensing bridge circuit can be configured to include a first sensing bridge comprising at least four resistive elements electrically connected to one another to form a first Wheatstone bridge configuration thereof, and a second sensing bridge comprising at least four resistive elements electrically connected to one another to form a second Wheatstone bridge configuration thereof. The first and second Wheatstone bridge configurations share the common geometrical center to provide at least two sinusoidal output signals thereof from which a linear signal curve can be extracted to determine travel associated with the magnet.

The present invention can thus be configured as an anisotropic magnetoresistive permalloy (NiFe) sensor that includes, for example, eight thin-film resistors arranged in two separate Wheatstone bridge configurations, which can respond to a varying magnetic field developed by a moving single bar magnet or a pair of permanent magnets. Sinusoidal electrical signals generated by the two sensing bridges can then be utilized to provide a linear signal that determines the position of the magnet. The approach disclosed herein thus utilizes permalloy thin-film magnetoresistors with uniaxial anisotropy in a saturated magnetic response mode in order to eliminate signal response variations due to changes in permanent magnet strengths and dimensions.

The novel features of the present invention will become apparent to those of skill in the art upon examination of the following detailed description of the invention or can be learned by practice of the present invention. It should be understood, however, that the detailed description of the invention and the specific examples presented, while indicating certain embodiments of the present invention, are provided for illustration purposes only because various changes and modifications within the spirit and scope of the invention will become apparent to those of skill in the art from the detailed description of the invention and claims that follow.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 depicts a schematic diagram of single bar magnet approach implemented in accordance with a preferred embodiment of the present invention;

FIG. 2 depicts a graph illustrating flux density magnitude variations associated with a single bar magnet movement in accordance with a preferred embodiment of the present invention;

FIG. 3 depicts a graph illustrating magnetic flux density angle variations associated with a single bar magnet movement in accordance with a preferred embodiment of the present invention;

FIG. 4 depicts a schematic diagram of a two-magnetoresistive sensing bridge implemented in accordance with a preferred embodiment of the present invention;

FIG. 5 depicts a graph illustrating anisotropic magnetoresistive sensor signals with single bar magnet movement in accordance with a preferred embodiment of the present invention;

FIG. 6 depicts a schematic diagram illustrating a two-bar magnet approach implemented in accordance with an alternative embodiment of the present invention;

FIG. 7 depicts a schematic diagram illustrating a two-bar magnet and one-pole piece approach in accordance with an alternative embodiment of the present invention;

FIG. 8 depicts a schematic diagram illustrating an alternative two-magnet approach in accordance with an alternative embodiment of the present invention;

FIG. 9 depicts a schematic diagram illustrating a two-magnet approach with a gap located between the magnets in accordance with an alternative embodiment of the present invention;

FIG. 10 depicts a schematic diagram illustrating a single magnet approach with one pole pair implemented in accordance with an alternative embodiment of the present invention;

FIG. 11 depicts a schematic diagram illustrating a two-magnet approach with a curved face profile implemented in accordance with an alternative embodiment of the present invention; and

FIG. 12 depicts a schematic diagram illustrating single magnet approach with one pole pair and curved face implemented in accordance with an alternative embodiment of the present invention.

### DETAILED DESCRIPTION OF THE INVENTION

The particular values and configurations discussed in these non-limiting examples can be varied and are cited merely to illustrate an embodiment of the present invention and are not intended to limit the scope of the invention.

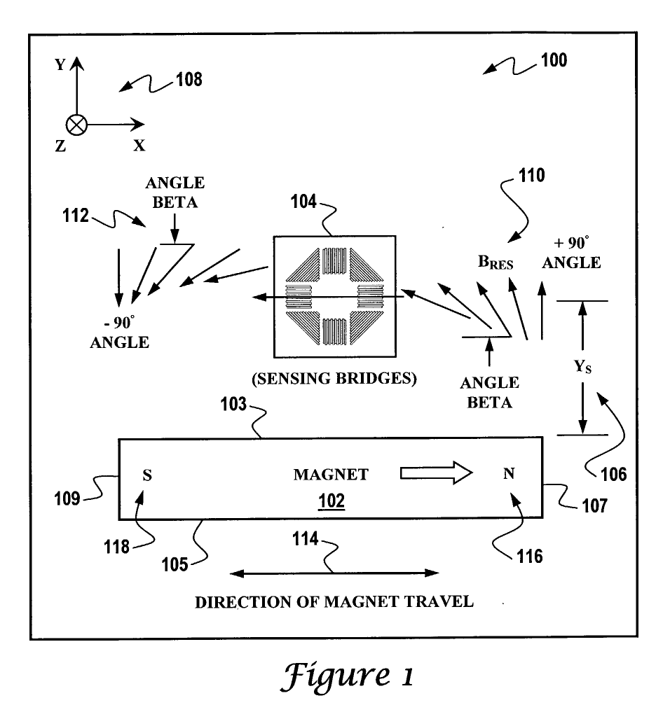

FIG. 1 illustrates a schematic diagram 100 of a single bar magnet approach implemented in accordance with a preferred embodiment of the present invention. A magnet 102 is shown configured as a single elongated bar magnetized along its length direction (i.e., from one end to the other). A north pole 116 occurs on one end face 107 of magnet 102 and a south pole 118 on the opposite end face 109 of magnet 102. Magnet 102 also includes a first side face 103 and a second side face 105. Coordinates 108 depicted in FIG. 1 represent directional X, Y and Z axis directions associated with schematic diagram 100. For a line of magnetic field locations that are centered on first side face 103 of magnet 102 (i.e., Z=0), at a fixed distance Yₛ 106 from first side face 103 and at points along the length of magnet, the magnetic flux density components generally known as Bₓ and B_{y} to be sensed generally vary in magnitude and change direction. For this approach both the magnetization of magnet 102 and movement directions thereof are parallel with one another.

For ease of understanding, the flux density components Bₓ and B_{y} can be converted to an equivalent resultant flux density Bᵣₑₛ=Square Root (Bₓ²+B_{y}²) at a resultant angle beta=inverse tangent (B_{y}/Bₓ). FIG. 1 illustrates the manner in which the resultant vector magnitude (Bᵣₑₛ) and direction angle (beta) change along a line at a distance from the side of the magnet where a sensor is to be located. One or more sensing bridges 104 are also illustrated in FIG. 1 along with respective arrows 110 and 112, which represent lines of magnetic force and angular directions thereof.

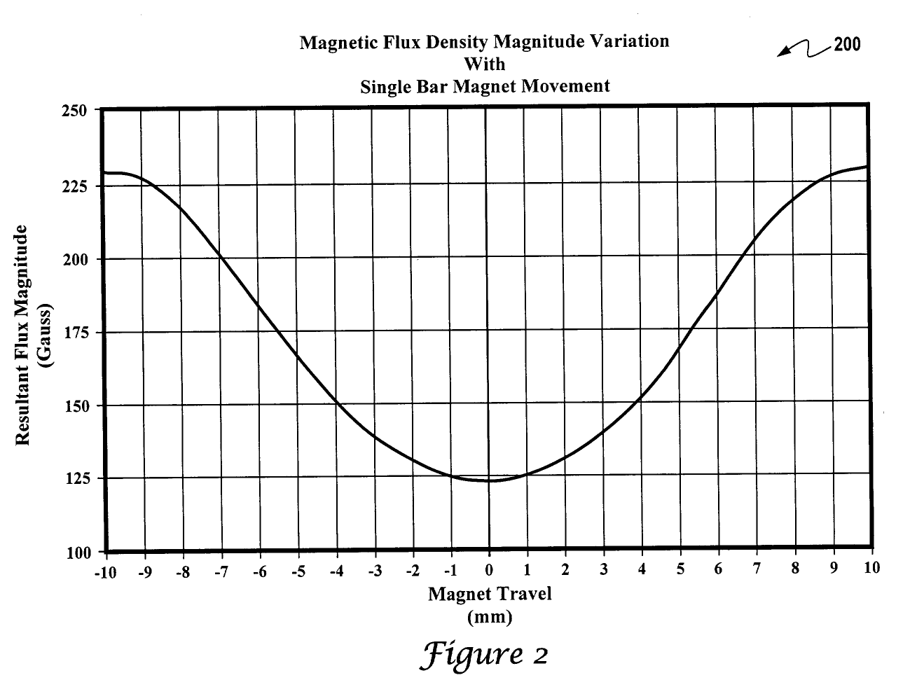

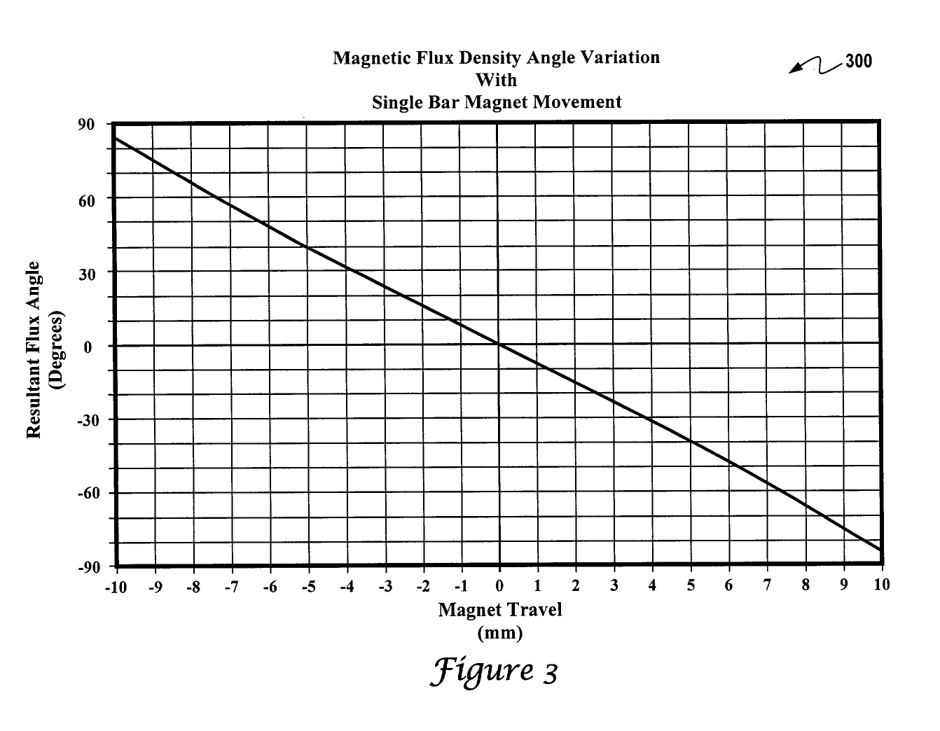

FIG. 2 depicts graph 200 illustrating flux density magnitude variations with a single bar magnet movement, in accordance with a preferred embodiment of the present invention. Additionally, FIG. 3 depicts a graph 300 illustrating magnetic flux density angle variations resulting from a single bar magnet movement in accordance with a preferred embodiment of the present invention. FIGS. 2 and 3 generally illustrate plots that demonstrate the manner in which the resultant flux density magnitude (Bᵣₑₛ) and angle (beta) can vary at points along a stationary magnet length at some fixed distance from the magnet side face.

It can be observed from FIG. 1 that the direction of the resultant magnetic field vector changes and rotates nearly 180° when traversing along a line of magnetic-field points from one end of the magnet length to the other. Likewise a rotating magnetic field angle of nearly 180° at a fixed field point or sensor location develops as a result of translational movement of the bar magnet equivalent to its length. A magnet attached, for example, to a movable mechanical linkage (not shown) associated with a clutch pedal or shift lever can provide a varying magnetic field at the sensor to thereby produce a sinusoidal shaped voltage signal, which can then be utilized to determine the distance the magnet traveled.

One skilled in the art and familiar with the response of a permalloy (NiFe) anisotropic magnetoresistive (AMR) sensor can appreciate that a change in sensor resistance can be achieved by changes in both the external applied magnetic field magnitude and the applied field angle with respect to the current direction within the resistor runners up to a certain level, which is commonly referred to in the art as a saturation mode. Once a saturated magnetic field magnitude is attained, the anisotropic magnetoresistance no longer changes with increasing magnetic flux/densities. Above a saturated magnitude level, only changes in the angle direction of the resultant magnetic field vector with respect to the current direction in the resistor runner legs will cause the magnetoresistor to change.

When designing a permanent magnet, it is important to select a magnet material and size that always maintains a saturated magnetic field magnitude level at the fixed sensor location over the desired range of magnet travel. It is preferable that the sensor design of the present invention have a magnetic field of 80 gauss or higher to maintain the magnetoresistive sensing elements in saturation.

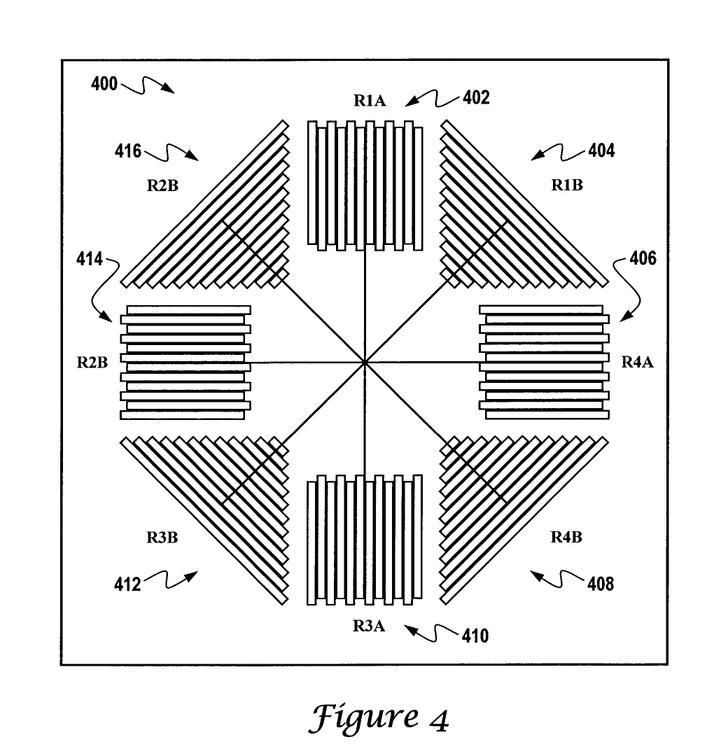

A single anisotropic magnetoresistive (AMR) permalloy sensing bridge (e.g., sensing bridge 104) configured from four thin-film resistors can thus be located in the x-y plane at a fixed point from the side face of the movable magnet to provide a sinusoidal voltage signal as the resultant flux density vector varies with magnet travel. Note that sensing bridge 104 of FIG. 1 is generally analogous to sensing bridge 400 of FIG. 4, which is described in further detail herein. A magnet travel position can then be determined from the sinusoidal signal voltage curve.

In accordance with one embodiment of the present invention, eight thin-film resistors can be electrically connected to form two separate Wheatstone sensing bridge configurations with a common geometrical center to provide two sinusoidal output signals, offset from one another, from which a linear signal curve can be extracted to determine magnet travel. Although, eight thin-film resistors can be implemented in accordance with a preferred embodiment of the present invention, it can be appreciated by those skilled in the art that this number can be varied, depending on design parameters and the intended use of the desired embodiments. Thus, an eight-resistor configuration, as disclosed herein, represents one possible embodiment and is not considered a limiting feature of the present invention.

FIG. 4 depicts a schematic diagram of a two-magnetoresistive sensing bridge 400 implemented in accordance with a preferred embodiment of the present invention. FIG. 4 generally illustrates a layout of eight resistors arranged between two Wheatstone sensing bridges. In FIG. 4, a first bridge circuit (i.e., Bridge A) can include rectangular shaped resistor patterns 402, 414, 410, and 406 (i.e., respectively labeled resistors R1A, R2A, R3A, and R4A), which can be electrically connected to form a single Wheatstone bridge. A second bridge circuit (i.e., Bridge B), whose resistors are oriented at 45° to those of Bridge A and triangular in their shape patterns, is configured from resistors 404, 416, 412, and 408 (i.e., respectively labeled resistors R1B, R2B, R3B, and R4B).

The four-axis symmetry of the eight-resistor layout pattern illustrated in FIG. 4 represents only one example of an arrangement of two sensing bridges. Other eight resistor patterns can be constructed, for example, having a less symmetrical or non-symmetrical arrangement but having all eight resistors with identical shape and size. An important point of this invention is to maintain at least two separate sensing bridges that share a common geometrical center point and are rotated from one another (in this case 45° although other angles are possible) to provide signals offset from one another.

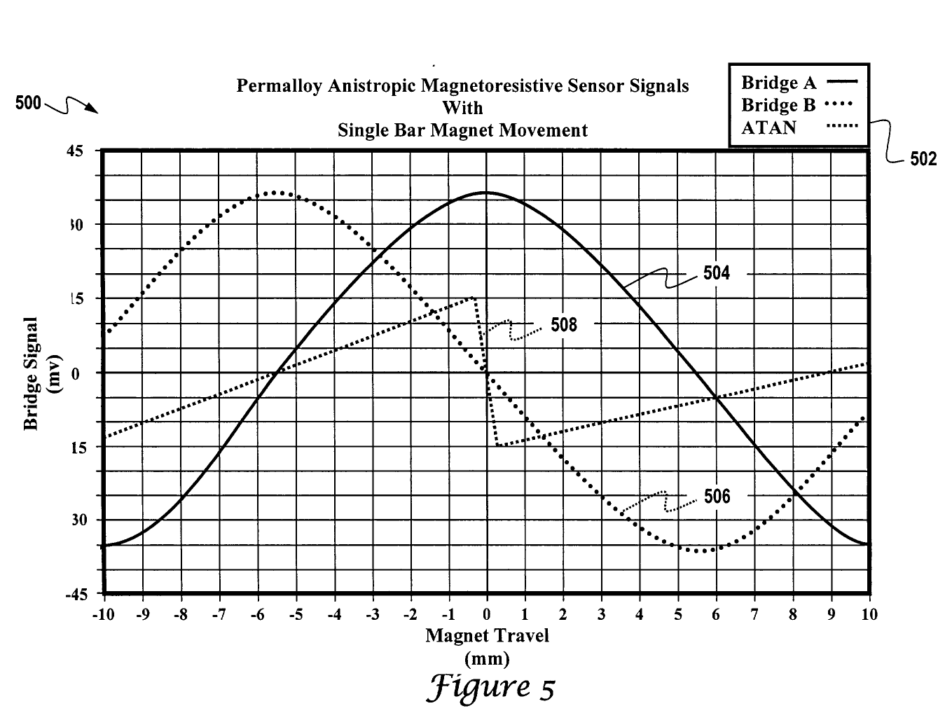

FIG. 5 depicts a graph 500 illustrating anisotropic magnetoresistive sensor signals with single bar magnet movement in accordance with a preferred embodiment of the present invention. FIG. 5 illustrates representative sinusoidal voltage signals from sensing Bridges A and B as a single bar magnet design moves, in this example, 20 mm (+−10 mm. from a center zero position). Note that legend box 502 indicates respective line plots associated with Bridge A or Bridge B. Line plot 504 is associated with Bridge A, while line plot 506 is associated with Bridge B. A linear signal curve (i.e., plot 508) representing the magnet travel position can be extracted utilizing the two separate sinusoidal bridge response curves as depicted in FIG. 5. As one example, a pair of linear saw tooth curves can be extracted utilizing Bridge signals A and B with a relation such as:

Saw tooth Voltage Signal=inverse tan[sin (Bridge Signal A)/cos (Bridge Signal B)]

In this example, the signal from Bridge B can be utilized to determine which one of the two linear saw tooth curves yields the magnet travel position. From FIG. 5, if the signal polarity of Bridge B is positive, then the linear saw tooth signal in the negative travel range of the graph is used to determine the magnet travel position (i.e., magnet has moved left from a center zero position). If the Bridge B signal is negative in value, then the linear saw tooth signal in the positive travel range yields the magnet position (i.e., the magnet has moved to the right from a center zero position). For a Bridge B signal near zero, the center of the magnet length along the movement direction coincides with the geometrical center of the sensing bridges.

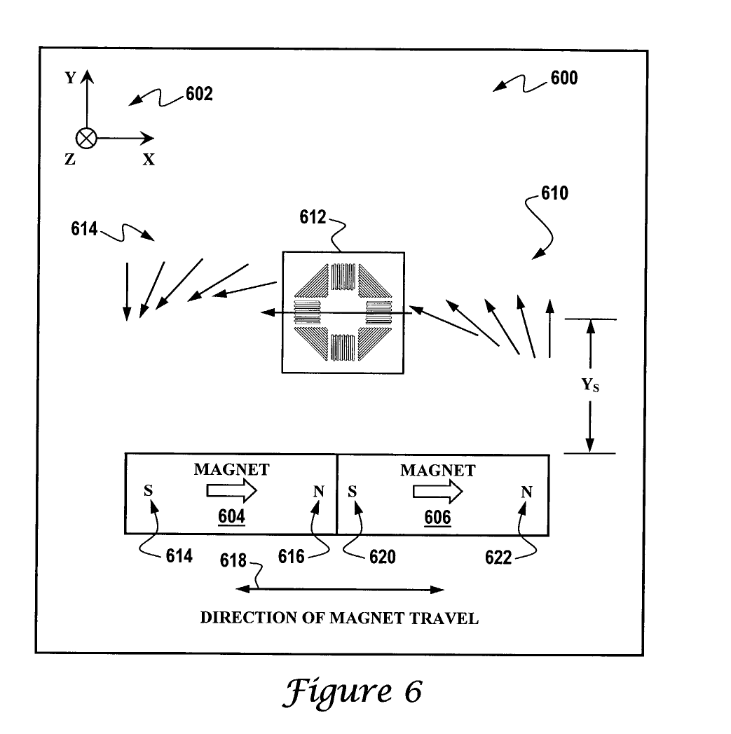

FIG. 6 depicts a schematic diagram 600 illustrating a two bar magnet approach in accordance with an alternative embodiment of the present invention. Coordinates 602 depicted in FIG. 6 represent directional X, Y and Z axis directions associated with schematic diagram 600. Two magnets 604 and 606 are illustrated in FIG. 6, such that magnet 604 includes a south pole 614 and a north pole 616. Magnet 606 includes a south pole 620 and a north pole 622. Also depicted in FIG. 6 are arrows 610 and 614 which represent lines of magnetic force and angular directions. Wheatstone sensing bridge 612 (analogous to sensing bridge 400 of FIG. 4) is located a fixed distance Yₛ from magnets 604 and 606Arrow 618 indicates the direction of magnet travel.

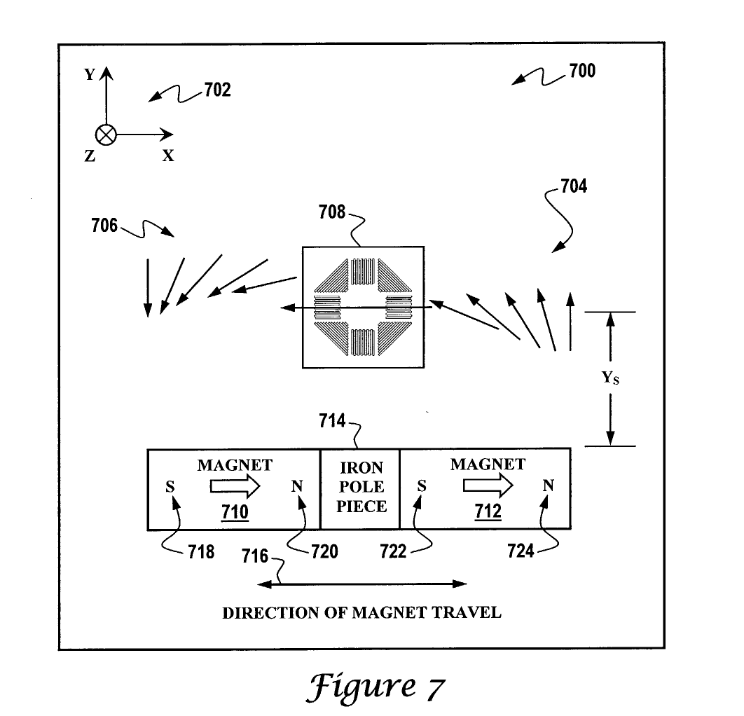

FIG. 7 depicts a schematic diagram 700 illustrating a two bar magnet and one pole piece approach in accordance with an alternative embodiment of the present invention. Coordinates 702 depicted in FIG. 7 represent directional X, Y and Z axis directions associated with schematic diagram 700. Two magnets 710 and 712 are indicated in FIG. 7, such that an iron pole piece 714 is disposed therebetween. Arrow 716 indicates the direction of magnet travel. Magnet 710 includes a south pole 718 and a north pole 720, while magnet 712 includes a south pole 722 and a north pole 724. The iron pole piece 714 is located between the north pole 720 of magnet 710 and south pole 722 of magnet 712. Arrows 706 and 704 represent lines of magnetic force and angular directions thereof and are located a fixed distance Yₛ from magnets 710 and 712. A sensing bridge is also shown in FIG. 7 and is generally analogous to sensing bridge 400 of FIG. 4.

Based on the foregoing it can thus be appreciated that FIGS. 6 and 7 illustrate alternative geometrical arrangements to the single magnetized bar magnet approach depicted in FIG. 1. FIG. 6 illustrates the manner in which a pair of permanent magnets are used to replace a single bar magnet to provide the same sensor signal as discussed previously. FIG. 7 illustrates, on the other hand, the manner in which a pair of permanent magnets can be separated by a short iron piece. In the configuration depicted in FIG. 7, the iron pole piece length should be designed so as to not alter the two separate bridge signals from a sinusoidal shape.

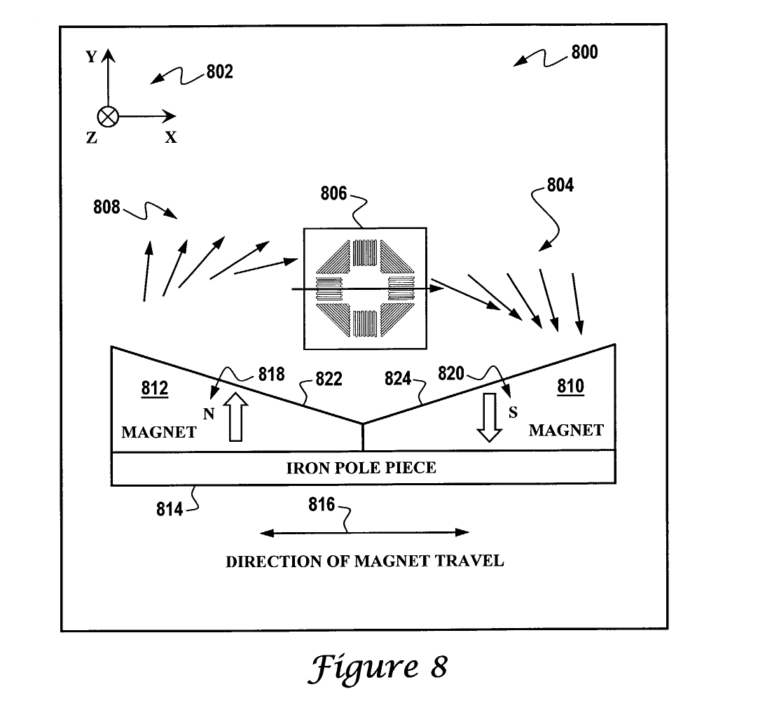

FIG. 8 depicts a schematic diagram 800 illustrating an alternative two-magnet approach in accordance with an alternative embodiment of the present invention. Schematic diagram 800 includes a magnet 812 and a magnet 810 disposed adjacent to an iron pole piece 814. Arrow 816 indicates a direction of magnet travel. Magnet 812 includes a north pole 818, while magnet 810 includes a south pole 820. Arrows 804 and 808 represent lines of magnetic force and angular directions thereof. Additionally, sensing bridge 806 is illustrated in FIG. 8, which is generally analogous to sensing bridge 400 of FIG. 4.

FIG. 8 thus illustrates an alternative approach to the sensing of a magnetic field variation on the side of an elongated single bar magnet in which a pair of permanent magnets 812 and 810 are located side-by-side. Magnets 810 and 812 are generally magnetized such that the magnetoresistive sensing bridge 806 senses magnetic field variations directly out in front of the magnet north and south pole faces. Magnet 812 includes a tapered side 822. Similarly magnet 810 includes a tapered side 824. Magnets 812 and 810 comprise a pair of tapered permanent magnets, which are oppositely magnetized, and may be mounted on a back support plate (e.g., iron pole piece 814). A translational movement of the pair of permanent magnets 810 and 812 can produce sinusoidal signals from sensing bridges A and B as discussed earlier with respect to the single bar magnet approach of FIG. 1.

For the configuration illustrated in FIG. 8, the magnetization directions of the magnet pair are perpendicular to the translational movement direction of the magnet pair, rather than parallel as in the single bar magnet approach depicted in FIG. 1. The usable sensing range for the single magnet of FIG. 1 is primarily determined by the magnetized length of the bar magnet. For the side-by-side pair of permanent magnets, two major design parameters influence the usable sensing range, those being the magnet pole profile shape (linear taper, curved face profile) plus the overall length of the magnets in the movement direction. As a result, the two-magnet approach has greater design flexibility for achieving signal linearity over a larger air gap range (i.e., sensor-to-magnet face distance) with less volume of permanent magnet material. Mounting the magnets on a slideable ferromagnetic iron back plate also helps to maintain a saturated magnetic field strength level at the sensor location while utilizing less magnet material and/or lower-cost, lower-strength magnet material as compared to the single bar magnet design.

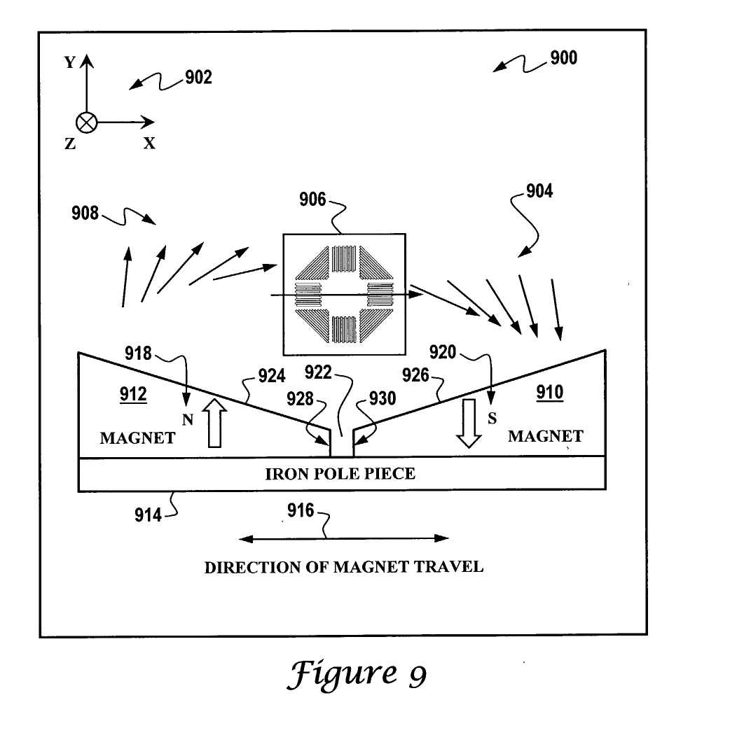

FIG. 9 illustrates a schematic diagram 900 illustrating a two-magnet approach with a gap 922 located between magnets 910 and 912 in accordance with an alternative embodiment of the present invention. Magnet 912 comprises a tapered magnet having a north pole 918, while magnet 910 comprises a tapered magnet having a south pole 920. Magnet 912 thus possesses a tapered side 924 while magnet 910 includes a tapered side 926. Additionally, magnet 912 includes a narrow side 928 and magnet 910 includes a narrow side 930. Gap 922 can thus be formed between narrow sides 928 and 930. Both magnet 910 and 912 are located beside an iron pole piece 914, which is generally disposed along an entire length or substantially the entire length of the first magnet and the magnet opposite the tapered sides thereof, including a portion of gap 922. Arrow 916 indicates the direction of magnet travel, while arrows 908 and 904 illustrate respective magnetic lines of force and angular directions thereof. Coordinates 902 represent X, Y, and Z directions associated with schematic diagram 900. Additionally, a sensing bridge 906 is illustrated in FIG. 9, wherein sensing bridge 906 is generally analogous to sensing bridge 400 illustrated in FIG. 4. FIG. 9 illustrates the manner in which the two permanent magnets 910 and 912 can be separated by the small gap 922 that is formed between magnets 912 and 910.

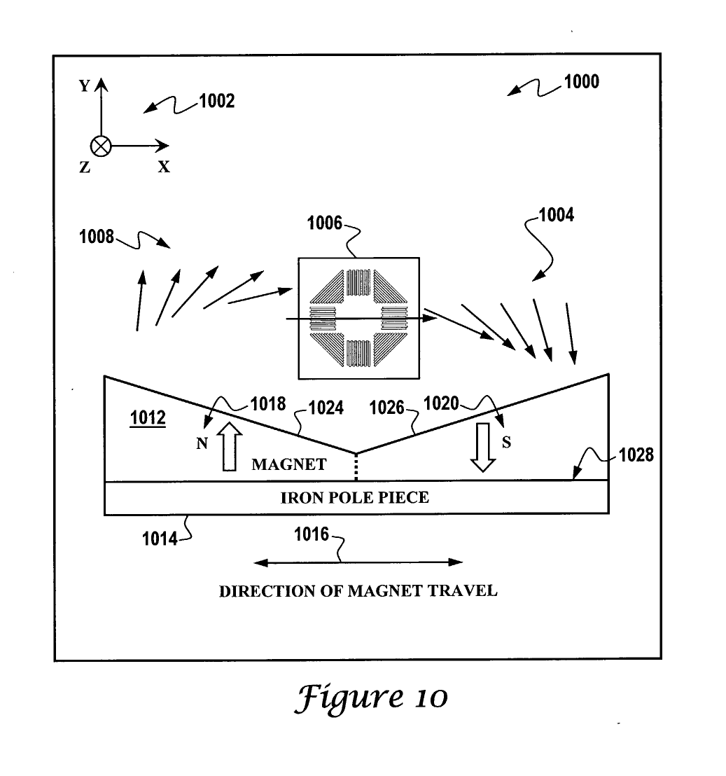

FIG. 10 depicts a schematic diagram 1000 illustrating a single magnet approach with one pole pair in accordance with an alternative embodiment of the present invention. Schematic diagram 1000 includes a single magnet 1012 having a north pole 1018 and a south pole 1020. Magnet 1012 is disposed adjacent to an iron pole piece 1014. Arrow 1016 generally indicates the direction of magnet travel. Arrows 1008 and 1004 illustrate magnetic lines of force and angular directions thereof. Coordinates 1002 generally indicated X, Y, and Z directions associated with schematic diagram 1000. Additionally, a sensing bridge 1006 is indicated in FIG. 10. Sensing bridge 1006 is analogous to sensing bridge 400 depicted in FIG. 4. Note that magnet 1012 can be configured as a single magnet having two tapered sides 1024 and 1026. Tapered side 1024 is associated with north pole 1018, while tapered side 1026 is associated with south pole 1020. Magnet 1012 also includes a non-tapered side 1028 located generally opposite tapered sides 1024 and 1026. Magnet 1012 thus comprises a single magnet having at least two tapered sides (i.e., tapered sides 1024 and 1026) thereof and includes a non-tapered side 1028 disposed adjacent to iron pole piece 1014. FIG. 10 generally illustrates how a single continuous volume of magnet can be magnetized with one pole pair (north and south) and be used in place of two separate permanent magnets described earlier.

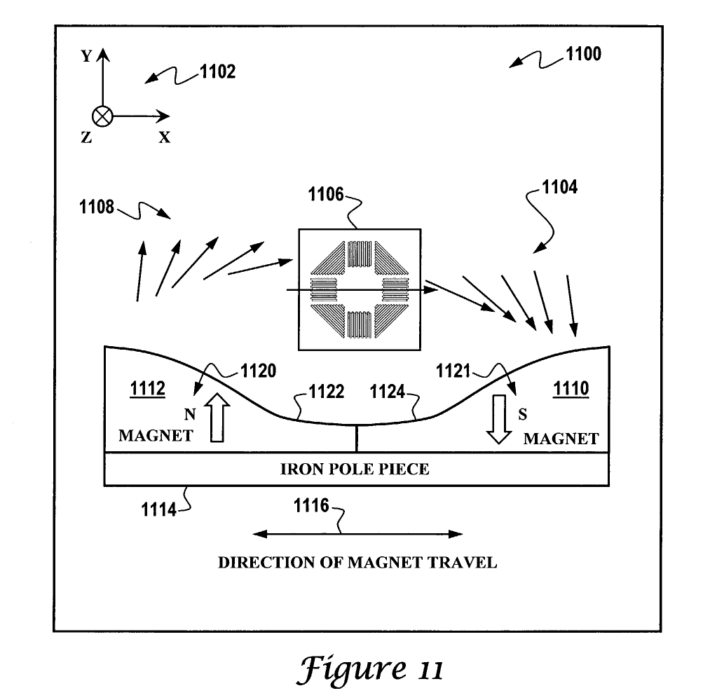

FIG. 11 depicts a schematic diagram 1100 illustrating a two-magnet approach with a curved face or curved side profile implemented in accordance with an alternative embodiment of the present invention. As illustrated in FIG. 11, coordinates 1102 generally indicate X, Y and Z directions associated with schematic diagram 1100. A magnet 1112 includes a north pole 1120 and a magnet 1110 includes a south pole 1121. Magnet 1112 possesses a curved side 1122, while magnet 1110 has a curved side 1124. Curved side 1122 of magnet 1112 is associated with north pole 1120, and curved side 1124 of magnet 1110 is associated with south pole 1121. Magnet 1112 is located beside magnet 1110. Both magnet 1112 and magnet 1110 are disposed adjacent to an iron pole piece 1114. Arrow 1116 generally indicates the direction of magnet travel, while arrows 1108 and 1104 represent magnetic lines of force and angular directions thereof. A sensing bridge 1106 is also illustrated in FIG. 11, which is generally analogous to sensing bridge 400 of FIG. 4. FIG. 11 thus illustrates the manner in which a curved side profile shape can be implemented. In this case the curved side profile shape should be designed so as not to alter the two separate bridge signals from a sinusoidal shape.

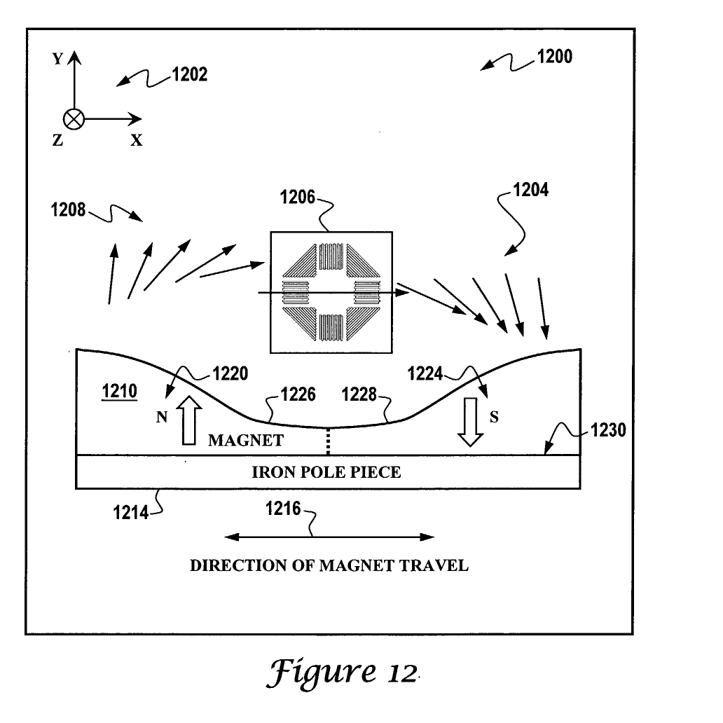

FIG. 12 depicts a schematic diagram 1200 illustrating a single magnet approach with one pole pair and a curved face (i.e., curved side), which may be implemented in accordance with an alternative embodiment of the present invention. As indicated in FIG. 12, coordinates 1202 generally represent X, Y, and Z directions associated with schematic diagram 1200. Additionally, a sensing bridge 1206 is illustrated in FIG. 12, which is generally analogous to sensing bridge 400 of FIG. 4. A single magnet 1210 includes a curved side 1226 and a curved side 1228. Additionally, magnet 1210 includes a north pole 1220 and a south pole 1224. Magnet 1210 is disposed adjacent to an iron pole piece 1214. An arrow 1216 indicates the direction of magnet travel, while arrows 1208 and 1204 indicate magnetic lines of force and angular directions thereof. Magnet 1210 generally comprises a single magnet having at least two curved sides (i.e., curved sides 1220 and 1228) thereof. Magnet 1210 also includes a non-curved side 1230 disposed adjacent to iron pole piece 1214. FIG. 12 thus illustrates how a curved face profile shaped magnet can be used as a single magnet with one pole pair.

The invention described herein can be implemented as a very reliable approach for providing linear position sensing capabilities in, for example, automotive applications where wide environmental temperature and vibration ranges are encountered. The present invention can be implemented as a non-contacting sensor solution comprising a stationary magnetoresistive sensing die and a movable magnet or magnet pair. There are no friction related problems or mechanical wear out of moving parts to develop, as found in contacting sensor approaches, that can limit the number of operations and mechanical life of the sensor.

A primary advantage of utilizing a permalloy magnetoresistive sensing bridge over a Hall-effect sensor is that the magnetic field level provided by the moving permanent magnet or magnets can easily be kept above the saturation level for a permalloy sensor. Keeping the permalloy sensing bridges in a saturation mode eliminates signal variations from stray magnetic fields, from changes in the permanent magnet strength that occur over a wide temperature range, and from variations in the sensing bridge-to-magnet spacing (air gap). Magnet travel position can continue to be accurately determined with significant changes occurring in the sensing bridge-to-magnet air gap distance caused by shock, vibration, and temperature induced expansion/contraction of the sensor parts.

Achieving nearly zero magnetostriction is another advantage of the present invention when utilizing a permalloy sensor with a material composition of, for example, 81% nickel and 19% iron. Mechanical stresses created during the sensor packaging build process or developed during wide temperature application ranges will have little effect on the permalloy magnetoresistive response. Hall-effect sensor signals, on the other hand, are significantly affected by mechanical stresses induced during the sensor build process and over temperature. Deliberate steps should be taken with Hall-effect designs (such as a quad-Hall element arrangement or commutated excitation of a single Hall element) along with stress-free silicon die packaging approaches to minimize the mechanical stress dependent contribution to the Hall signal when used to sense magnet movement.

By utilizing two separate sensing bridges with identical resistance, elaborate signal conditioning electronics for temperature compensation of the predictable temperature-dependent changes of the permalloy bridge resistance and sensitivity response are not required. By dividing the two separate sensing bridge signals in the example presented (e.g., inverse tan [sin(Bridge Signal A)/cos(Bridge Signal B)]), the temperature dependent signal changes from the magnetoresistive responses of the two separate permalloy sensing bridge signals are divided or ratioed out and disappear.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

The embodiments of the invention in which an exclusive property or right is claimed are defined as follows. Having thus described the invention what is claimed is:

1. A sensor for detecting linear position, said sensor comprising:
at least one sensing bridge circuit configured from at least two separate sensing bridges that share a geometrical center and are rotated from one another to provide signal offsets thereof; and
at least one magnet having a north pole and a south pole thereof, wherein said at least one sensing bridge circuit is disposed a distance from said at least one magnet to provide sinusoidal shaped signals which can be utilized to determine travel or distance and thus a linear position associated with said at least one magnet.

2. The sensor of claim 1 wherein said at least two separate sensing bridges comprise:
a first sensing bridge comprising at least four resistive elements electrically connected to one another to form a first Wheatstone bridge configuration thereof; and
a second sensing bridge comprising at least four resistive elements electrically connected to one another to form a second Wheatstone bridge configuration thereof, wherein said first and second Wheatstone bridge configurations share said geometrical center to provide at least two sinusoidal output signals thereof from which a linear signal curve is extracted to determine travel associated with said at least one magnet.

3. The sensor of claim 1 wherein said at least four resistive elements of said first sensing bridge and said at least four resistive elements of said second sensing bridge comprise thin film resistors.

4. The sensor of claim 3 wherein said thin film resistors comprise thin film magnetoresistors.

5. The sensor of claim 1 wherein said at least one sensing bridge circuit comprises eight resistors symmetrically arranged about said geometrical center, such that said eight resistors are identical to one another in shape and size.

6. The sensor of claim 1 wherein said at least one magnet comprises a single elongated bar magnetized along a length of said single elongated bar.

7. The sensor of claim 1 wherein said at least one magnet comprises a first magnet and a second magnet disposed adjacent to one another.

8. The sensor of claim 7 further comprising an iron pole piece adjacent the at least one magnet.

9. The sensor of claim 1 wherein an iron pole piece is disposed between said first magnet and said second magnet.

10. The sensor of claim 1 wherein said first magnet comprises a tapered side thereof and said second magnet comprises a tapered side thereof, such that an iron pole piece is disposed along an entire length of said first magnet and said second magnet opposite said tapered sides thereof.

11. The sensor of claim 10 wherein said first magnet comprises a narrow side and said second magnet comprises a narrow side, such that a gap is formed between said narrow side of said first magnet and said narrow side of said second magnet.

12. The sensor of claim 1 wherein said at least one magnet comprises a single magnet having at least two tapered sides thereof and wherein said at least one magnet includes a non-tapered side disposed adjacent to an iron pole piece.

13. The sensor of claim 8 wherein said first magnet comprises a curved side thereof and said second magnet comprises a curved side thereof.

14. The sensor of claim 1 further comprising an iron pole piece, wherein said at least one magnet comprises a single magnet having at least two curved sides thereof and wherein said at least one magnet includes a non-curved side disposed adjacent to the iron pole piece.

15. A sensor for detecting linear position, said sensor comprising:
at least one sensing bridge circuit comprising at least two separate sensing bridges including a first sensing bridge having at least four resistive elements electrically connected to one another to form a first Wheatstone bridge configuration thereof and a second sensing bridge that includes at least four resistive elements electrically connected to one another to form a second Wheatstone bridge configuration thereof, such that said first and second Wheatstone bridge configurations have a common geometrical center; and
at least one magnet having a north pole and a south pole thereof, wherein said at least one sensing bridge circuit is disposed a distance from at least one magnet to determine a linear position associated with said at least one magnet.

16. A method for detecting linear position using a magnetic sensor, said method comprising the steps of:
configuring at least one sensing bridge circuit from at least two separate sensing bridges that have a common geometrical center and are rotated from one another to provide signal offsets thereof; and
associating said at least one sensing bridge circuit with said at least one magnet having a north pole and a south pole thereof; and
disposing said at least one sensing bridge circuit a distance from said at least one magnet to provide sinusoidal shaped signals which can be utilized to determine travel and, thus, a linear position associated with said at least one magnet.

17. The method of claim 16 further comprising the step of:
configuring said at least two separate sensing bridges to comprise:
a first sensing bridge comprising at least four resistive elements electrically connected to one another to form a first Wheatstone bridge configuration thereof; and
a second sensing bridge comprising at least four resistive elements electrically connected to one another to form a second Wheatstone bridge configuration thereof, wherein said first and second Wheatstone bridge configurations share said common geometrical center to provide at least two sinusoidal output signals thereof from which a linear signal curve is extracted to determine travel associated with said at least one magnet.

18. The method of claim 16 further comprising the step of:
configuring said at least four resistive elements of said first sensing bridge and said at least four resistive elements of said second sensing bridge to comprise thin film resistors.

19. The method of claim 18 further comprising the step of:
configuring said thin film resistors to comprise thin film magnetoresistors.

20. The method of claim 16 further comprising the step of:
configuring said at least one sensing bridge circuit to comprise eight resistors symmetrically arranged about said common geometrical center, such that said eight resistors are identical to one another in shape and size.

21. The method of claim 16 further comprising the step of:
configuring said at least one magnet to comprise a single elongated bar magnetized along a length of said single elongated bar.

22. The method of claim 16 further comprising the step of:
configuring said at least one magnet to comprise a first magnet and a second magnet disposed adjacent to one another.

23. The method of claim 22 further comprising the step of:
associating said first magnet and said second magnet with an iron pole piece.

24. The method of claim 16 further comprising the step of:
disposing an iron pole piece between said first magnet and said second magnet.

25. The method of claim 16 further comprising the step of:
configuring said first magnet to comprise a tapered side thereof and said second magnet to comprise a tapered side thereof, such that an iron pole piece is disposed along an entire length of said first magnet and said second magnet opposite said tapered sides thereof.

26. The method of claim 25 further comprising the step of:
configuring said first magnet to comprise a narrow side and said second magnet to comprise a narrow side, wherein a gap is formed between said narrow side of said first magnet and said narrow side of said second magnet.

27. The method of claim 16 further comprising the step of:
configuring said at least one magnet to comprise a single magnet having at least two tapered sides thereof wherein said at least one magnet includes a non-tapered side disposed adjacent to an iron pole piece.

28. The method of claim 23 further comprising the step of:
configuring said first magnet to include a curved side thereof; and
configuring said second magnet to comprise a curved side thereof.

29. The method of claim 16 further comprising the step of:
configuring said at least one magnet to comprise a single magnet having at least two curved sides thereof; and
disposing a non-curved side of said at least one magnet adjacent to an iron pole piece.

30. A method for detecting linear position using a magnetic sensor, said method comprising the steps of:
configuring said magnetic sensor to comprise at least one sensing bridge circuit that includes at least two separate sensing bridges;
configuring said at least two separate sensing bridges to include a first sensing bridge having at least four resistive elements electrically connected to one another to form a first Wheatstone bridge configuration thereof and a second sensing bridge that includes at least four resistive elements electrically connected to one another to form a second Wheatstone bridge configuration thereof;
arranging said first and second Wheatstone bridge configurations, such that said first and second Wheatstone bridge configurations share a said common geometrical center; and
configuring said magnetic sensor to include at least one magnet having a north pole and a south pole thereof; and
disposing said at least one sensing bridge circuit a distance from at least one magnet to provide sinusoidal shaped signals which can be utilized to determine travel and, thus, a linear position associated with said at least one magnet.
